(19) United States
(12) Patent Application Publication
(10) Pub. No.: US 2009/0223700 A1
(43) Pub. Date: Sep. 10, 2009

(54) THIN FLEXIBLE CIRCUITS

(75) Inventors: Daniel Youngner, Maple Grove, MN (US); Son Thai Lu, Plymouth, MN (US); Helen Chanhvongsak, Lakeville, MN (US); Lisa Lust, Plymouth, MN (US); Doug Carlson, Woodbury, MN (US)

Correspondence Address: HONEYWELL INTERNATIONAL INC.;PATENT SERVICES, 101 COLUMBIA ROAD, P O BOX 2245, MORRISTOWN, NJ, 07962-2245, US

(73) Assignee: HONEYWELL INTERNATIONAL INC., Morristown, NJ (US)

(21) Appl. No.: 12/042,897

(22) Filed: Mar. 5, 2008

(51) Int. Cl. H05K 1/02; H01B 13/00

(52) U.S. Cl. 174/254; 216/13

(57) ABSTRACT

An approach for making thin flexible circuits. A layer of dielectric may have one or two surfaces coated with metal. The dielectric and the metal may each have a sub-mil thickness. The dielectric may be held in a fixture for fabrication like that of integrated circuits. The metal may be patterned and have components attached. More layers of dielectric and patterned metal may be added to the flexible circuit. Also bond pads and connecting vias may be fabricated in the flexible circuit. The flexible circuit may be cut into a plurality of smaller flexible circuits.

The U.S. Government may have certain rights to the present invention.

### BACKGROUND

The invention pertains to circuit boards, and particularly their fabrication. More particularly, the invention pertains to flexible circuits.

### SUMMARY

The invention is an approach for thin flexible circuits.

### BRIEF DESCRIPTION OF THE DRAWING

FIG. 1 is a diagram of a flex circuit with a front and/or back copper-coated sub-mil dielectric film stretched across a ring fixture;

FIGS. 2a-2d are diagrams illustrating a depositing, patterning, and etching additional films of various metals, which may afterwards be covered with a dielectric;

FIGS. 3a-3d are diagrams showing bond-pads patterned with a two-layer resist;

FIGS. 4a-4e are diagrams showing aspects for making a flex circuit;

FIGS. 5a-5h are diagrams showing an approach for a flexible circuit having two levels of components;

FIGS. 5i-5k are diagrams showing an approach for a conductive via between two levels of components;

FIGS. 6a-6h show the adding of circuit components on the other side of the flexible circuit; and

FIGS. 7a-7i show the adding of a via at the other side of the flexible circuit.

### DESCRIPTION

Flexible circuit (flex circuit) technology may often result in feature sizes that are typically several tens of microns or larger. Additionally, flex-circuit technology may offer a rather limited set of available materials (typically copper and polyimide layers that range from several microns to several tens of microns thick). Often, there is a need for flex circuits with feature sizes that are smaller, films that are thinner, materials that are more flexible, and/or materials that are non-standard, relative to the state-of-the-art.

The present invention combines IC (integrated circuit) technology with flex-circuit technology to address the need of smaller size. In one illustrative example, ½ mil (12.7 micron) Kapton™ material with about 9 microns (0.35 mil) of plated copper on either or both sides may be used. The Kapton™-copper may be cut into a six-inch diameter circle and clamped in a ring-fixture that stretches the material taught. Other sub-mil dielectric material with sub-mil metal on either or both sides of the dielectric may be used for a flexible circuit.

As desired or needed, the lower copper surface may be protected with a photoresist and/or a six-inch diameter silicon, Pyrex™, or glass wafer which may be either placed or weakly bonded beneath the dielectric film for additional mechanical support. The six-inch supported structure may now be processed in a similar manner as a conventional six-inch silicon wafer. Other sizes may be implemented.

An upper copper layer can be patterned with photoresist and wet-etched, ion-milled, or additionally plated. Additional conductive, semi-insulative, or resistive thin-film or thick-film materials such as platinum, chrome, or NiCr (nickel-chrome alloy) may be deposited, patterned, and etched. A polyimide dielectric may be spin-applied, cured, photo-patterned, and etched. Bond pad metal such as Ti/Ni/Au (a layered structure of titanium, nickel, and gold) may be evaporated and deposited.

Through-hole vias may be etched in the Kapton™, allowing electrical contact to be made to the copper on the back-side of the structure. The front surface may be protected with, for example, a photoresist, and the back-side can be patterned with copper, dielectrics, various other metals, and so forth, in a similar way that the front-side is patterned. Virtually all of the thickness dimensions on some or all layers of the finished structure may be near-micron or sub-micron, allowing for dense flex circuits with high levels of integration. Once all of the passive layers have been patterned, ICs and/or other dies may be bonded to either the front surface or the back surface of the wafer. Either before or after attaching a die, the six-inch wafer may be patterned and O₂-RIE'ed (i.e., oxygen plasma reactive ion etched) to release numerous separate flex circuits, much in the way that one dices a silicon wafer to release separate silicon dies.

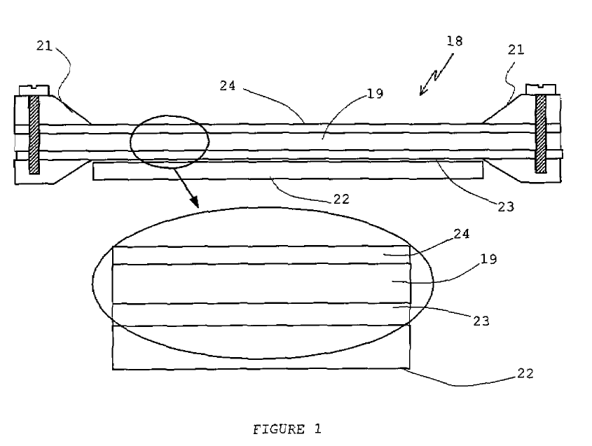

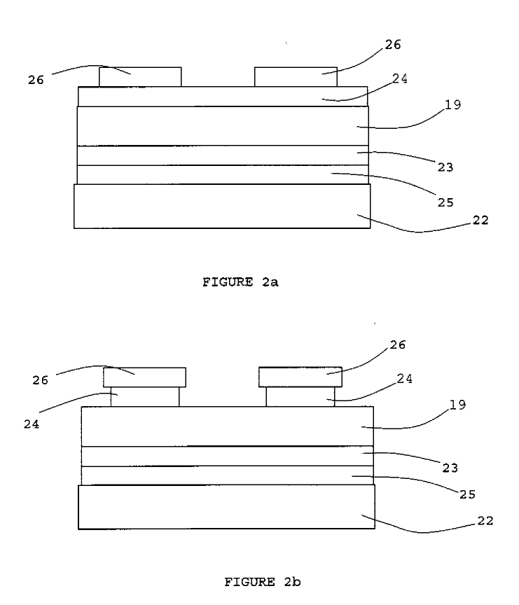

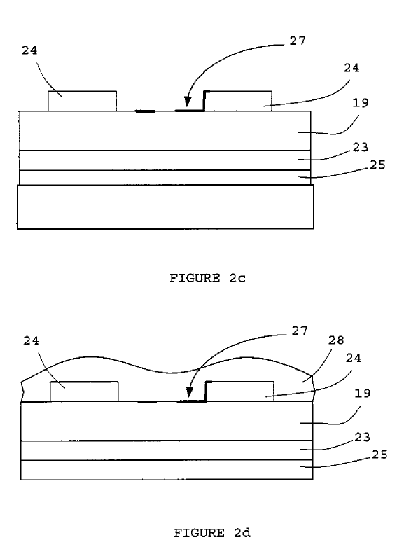

The following approaches are shown with several sets of steps for making the half-mil Kapton™ flex circuits. A first step may be to stretch the front-and-back copper-coated 0.5-mil Kapton™ film 18 across an approximately six-inch inside diameter ring fixture 21, as shown in FIG. 1. There may be about 9 microns of copper 24 on the top side of the 0.5-mil Kapton™ core 19 and about 9 microns of copper 23 on the bottom side of the dielectric core 19. An optional glass or silicon support wafer 22 may be situated at the bottom of film 18 to hold the film firm. Another step may be to protect the back-side copper 23 with a photo resist 25 as shown in FIG. 2a. Also, the front-side copper 24 may be coated with a photoresist 26, photo-patterned and wet etched, as shown in FIGS. 2a and 2b, respectively.

As indicated in a diagram of FIG. 2c, another step may be to optionally deposit, pattern, and etch additional films 27 such as platinum, chrome, or NiCr which make up circuitry such as resistors, components, and the like. One may spin on a polyimide dielectric 28 with sufficient thickness to coat all materials of the items 24 and 27 on the surface of core 19, as shown in FIG. 2d. The polyimide 28 may be cured. Cured polyimide may be like the material of Kapton™.

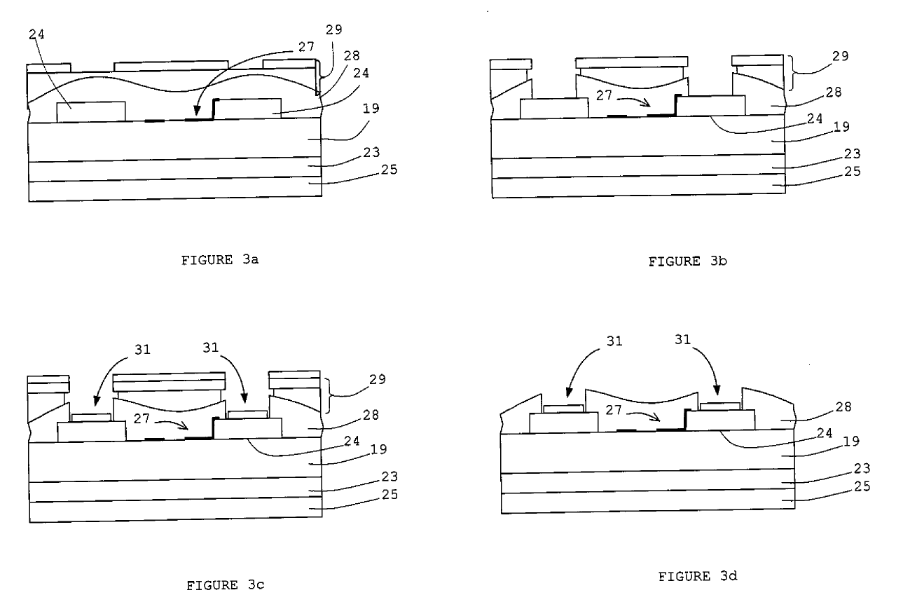

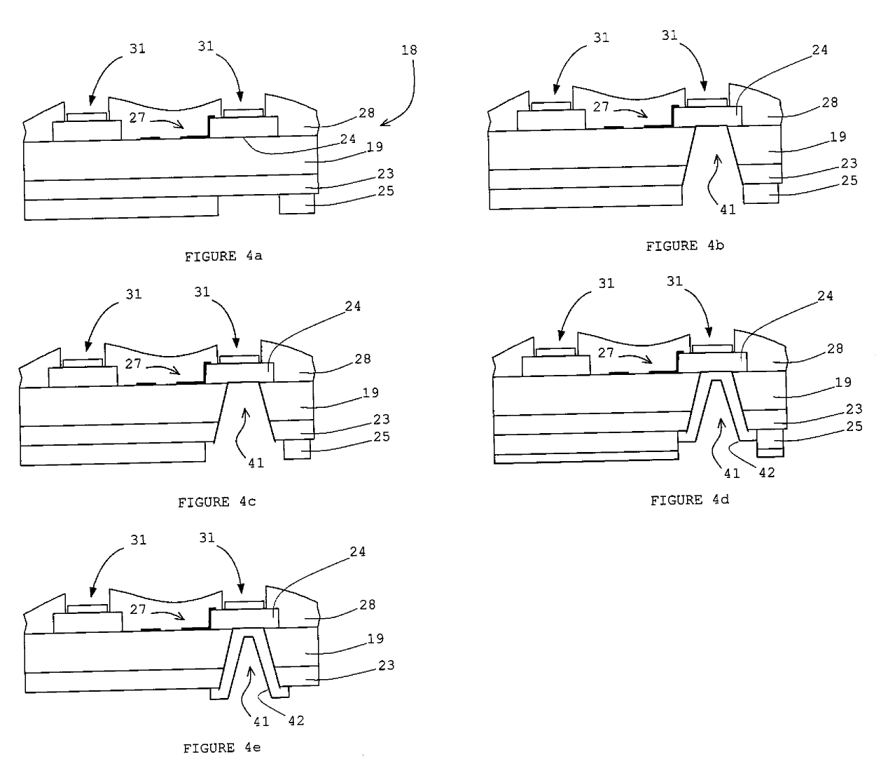

A diagram of FIG. 3a illustrates a next step which may then be to put on a two layer resist 29. The two-layer resist 29 may have a lift-off resist (LOR) with a photoactive resist, having patterns, on the LOR. The LOR tends to provide a flat surface for the photosensitive resist layer, even though the surface that the LOR is put on is not necessarily flat. A pattern on the photosensitive resist layer may be for putting bond pads on copper 24 in the present example. One may O₂-RIE the LOR and the polyimide 28 in FIG. 3b. Then Ti/Ni/Au material 31 may be deposited as the bond pads on copper 24, as in FIG. 3c. The two-layer resist 29 may be removed, as in FIG. 3d, or retained intact until after the holes are patterned and made with O₂-RIE holes through the Kapton™ 19 from the back-side copper 23, as shown in FIGS. 4a-4e.

The first steps may be repeated on the back-side of the wafer 19 for more flexible circuitry. The next step may be to pattern and O₂-RIE through the Kapton™, cutting and separating the six-inch film into separate flex-circuit substrates. Another step may be to solder-bond or wire-bond the die to the front-side and back-side of the circuit. These last two steps could be done in reverse order.

FIG. 4a shows a pattern of photoresist 25 for making a connection via through the film circuit 18. A hole for a via 41 may be etched through layers 23 and 19 to copper 24, as shown in FIG. 4b. In FIG. 4c, the pattern of photoresist 25 may be adjusted or replaced to provide exposure of an edge of copper layer 23 at via 41, as shown in FIG. 4c.

A conductive layer such as platinum, chrome or NiCr material 42 may be deposited to make conductive the via 41 from layer 23 to copper layer 24 or pad, as shown in FIG. 4d. Photo-resistive layer 25 may be removed as noted in FIG. 4e. Copper layer 23 may be patterned with circuit elements before or after making the conductive via or vias 41. Several layers of circuitry including vias may be added to the bottom and/or top side of the flex circuit in FIG. 4e.

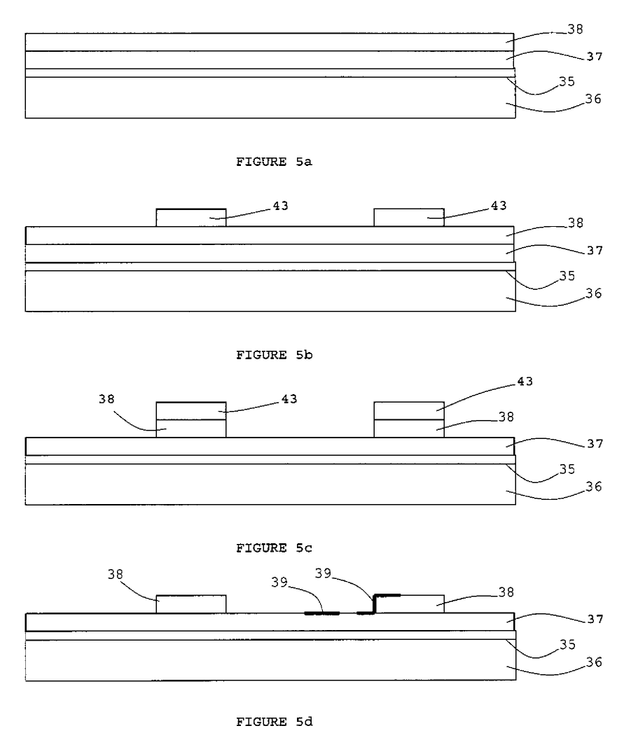

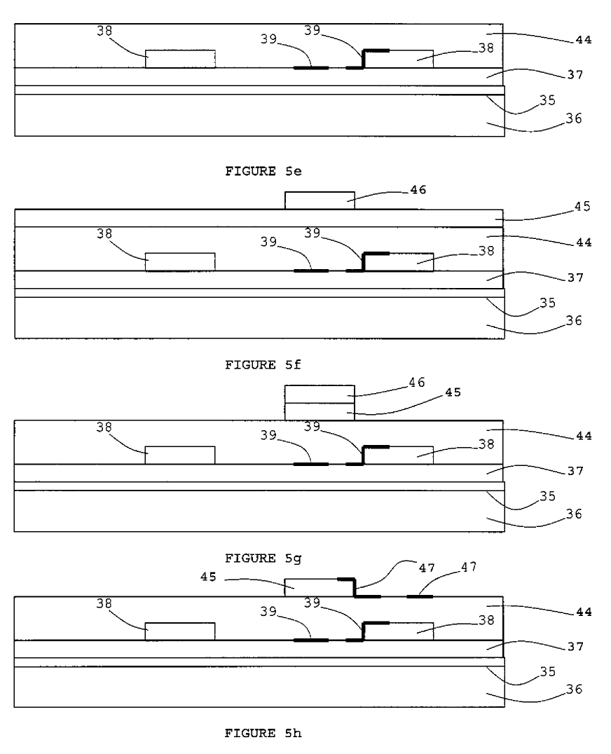

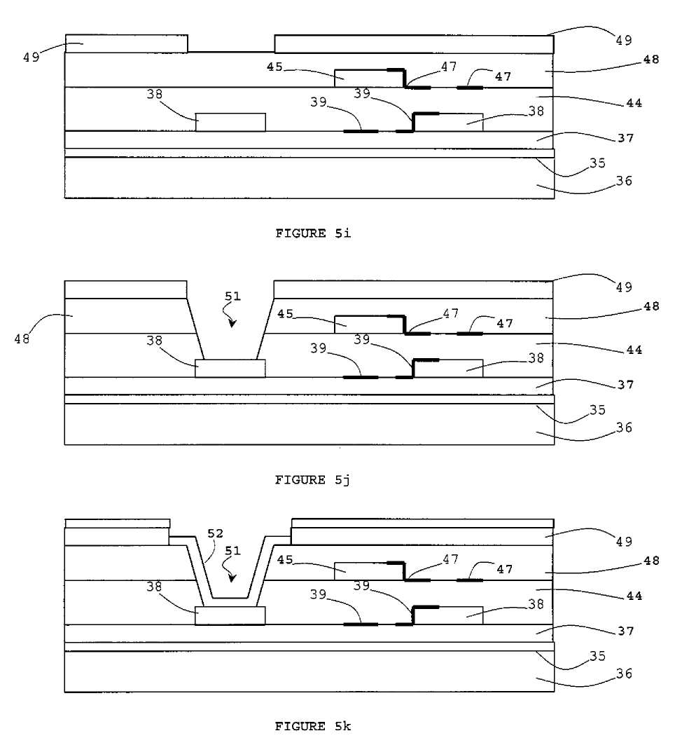

FIG. 5a is a diagram of aspects of another flexible circuit approach, which may be effected with the following steps. One step may be to apply a sacrificial layer 35 on a silicon wafer 36. Layer 36 may be a support for the flex circuit being designed. Layer 35 may be molybdenum or TiW (which can later be removed with a chemical such as H₂O₂ that does not affect the other materials in the flex circuit). Other sacrificial materials may be used. The next step may be to spin-apply any desired thickness of polyimide 37 (chemically similar to Kapton™) on layer 35. The polyimide 37 may be cured at up to 400 degrees C. Another step may be to apply a layer 38 of metal such as copper.

A photoresist layer 43 may be applied and patterned as shown in FIG. 5b. Metal 38 may be etched as shown in FIG. 5c and the resist 43 removed in FIG. 5d. The next step may be to apply or deposit, and pattern conductors and resistive materials 39 of choice (e.g., copper conductors, platinum resistors and other components) on layer 37 and metal 38, copper pads and layer 38. Another step may be to spin-apply a thin layer 44 of polyimide—thick enough to cover the topography in the conductive and resistive items 38 and 39 and components, respectively, in FIG. 5e. Another step may be to pattern and etch one or more via holes thorough the newly applied polyimide layer, similar to the way of FIGS. 4a through 4e. The previous steps may be repeated as many times as desired to build up a multi-layer flex circuit. Another step may be to pattern the outline of the separate flex circuits and oxygen-RIE through the base polyimide 37. Then separate flex circuits may be released by etching away the sacrificial layer put down in a beginning step.

In FIG. 5e, a layer 44 of polyimide may be applied on components 38 and 39. A copper 45 may be deposited on the layer 44. On the copper 45, a mask 46 may be placed, as in FIG. 5f. The mask may be implemented to lay out conductors and components. Not masked copper 45 may be removed with an appropriate etching. Remaining would be the copper conductors and components 45 as in FIG. 5g. Mask 46 may be removed, and resistive and other component materials may be deposited as in FIG. 5h. A layer 48 of, for instance, polyimide may be deposited on components 45 and 47, and areas of layer 44, as in FIG. 5i.

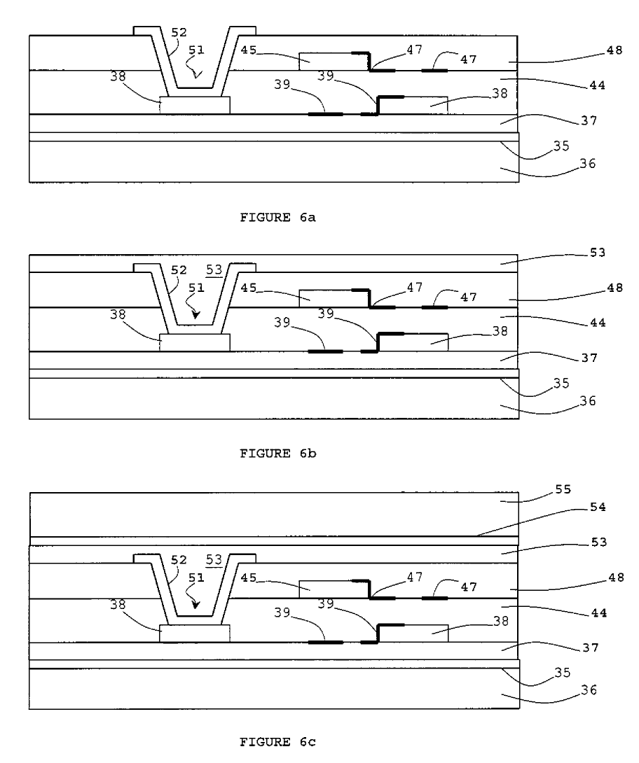

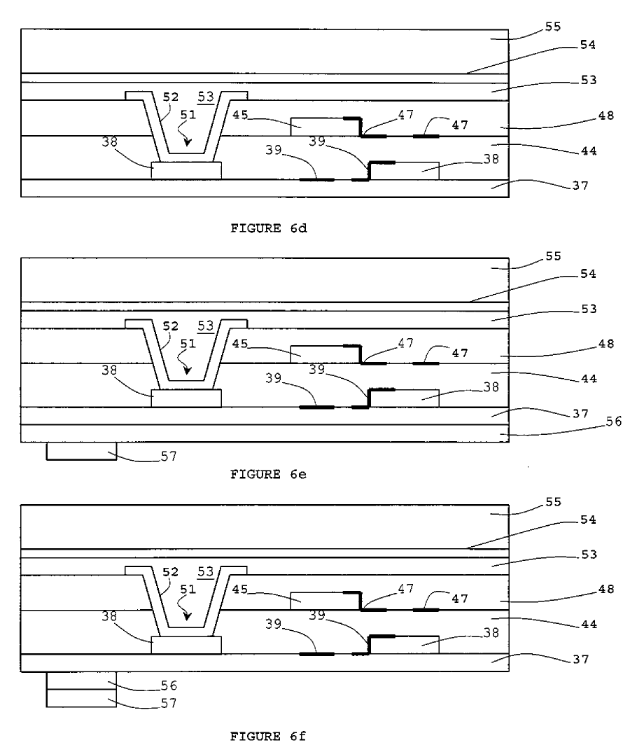

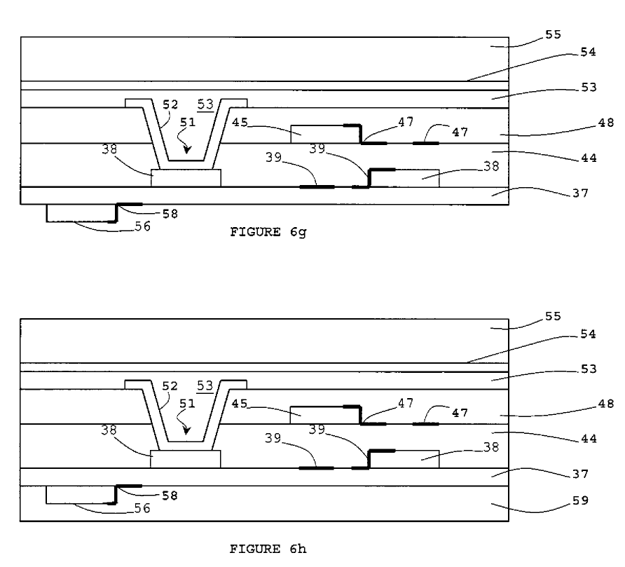

A mask 49 for developing a via may be put on layer 48, as indicated in FIG. 5i. In FIG. 5j, an etching through an opening in the mask 49 through layer 48 and into layer 44 may result in a via 51 to metal 38. The edges of mask 49 may be cut back from via 51 or a new mask may replace the previous mask to expose some surface of layer 48 proximate to via 51. Then a metal 52 may be deposited in via 51, as shown in FIG. 5k, to provide an electrical connection from metal 38 to the surface of layer 48. Mask 49 may be removed as in FIG. 6a.

A polyimide or like-material layer 53 may be applied on layer 48 and via 51, as in FIG. 6b. Then a sacrificial layer 54 of molybdenum, TiW, or other sacrificial material, may be put on layer 53 with a silicon layer 55 on layer 54 for support of the flex circuit, as in FIGS. 6b and 6c. The sacrificial layer 35 may be removed thereby releasing the silicon support layer 36 resulting in the flex circuit shown in FIG. 6d. A metal layer 56, such as copper, may be put on layer 37 along with a mask 57, as in FIG. 6e. Unmasked portions of layer 56 may be etched resulting in a metal pad or component 56 as in FIG. 6f. In FIG. 6g, the mask 57 may be removed and metal components 58 of a circuit may be deposited on layer 37 and metal 56. A polyimide or like material layer 59 may be applied on layer 37, components 58 and metal 56, as in FIG. 6h.

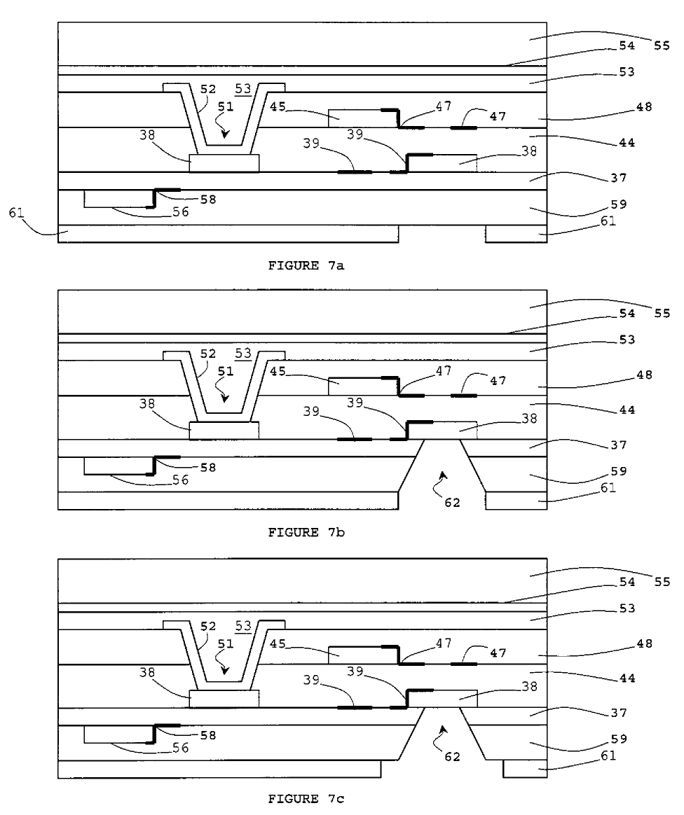

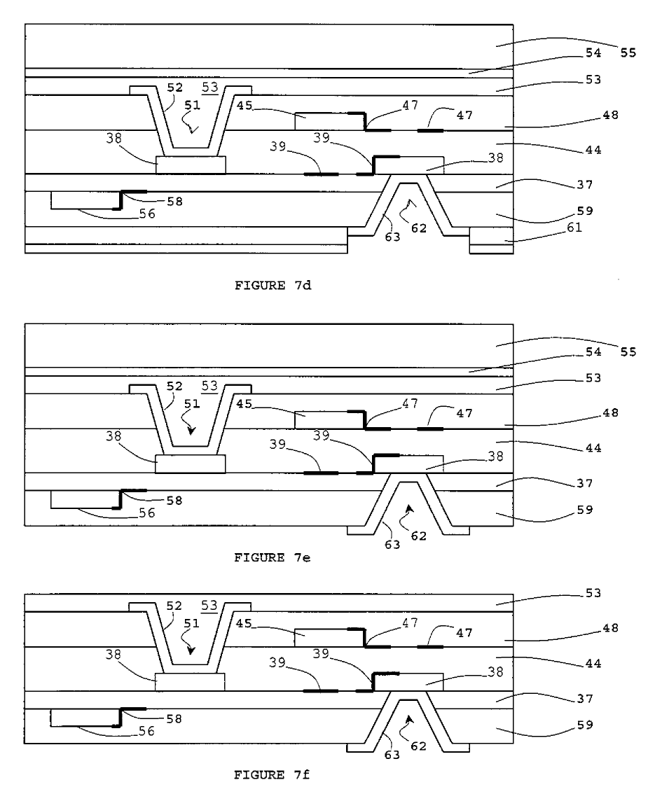

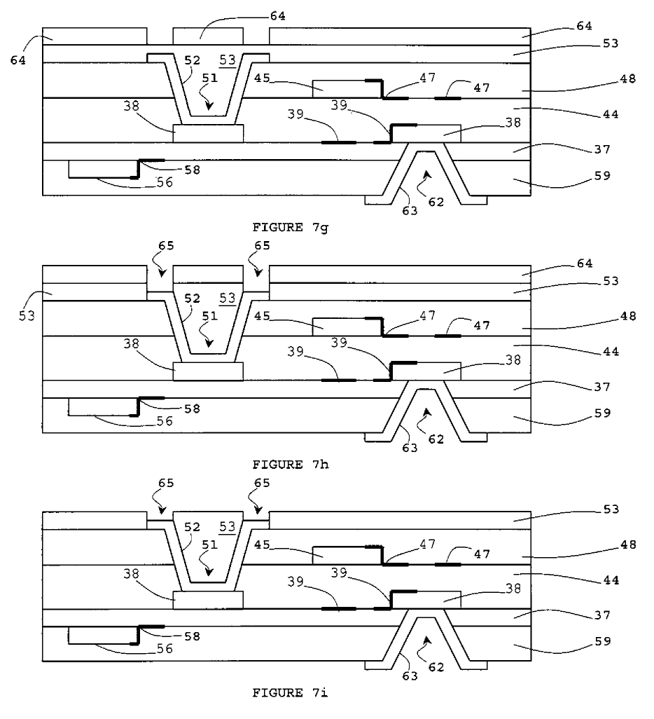

In FIG. 7a, a mask 61 may be placed on layer 59 for etching a via 62 through layers 59 and 37 to metal 38, as in FIG. 7b. FIG. 7c shows masking 61 with an edge at via 62 moved back exposing more surface of layer 59. A metal 63 may be deposited on the surface where the via 62 is situated in FIG. 7d. In FIG. 7e, the mask 61 may be removed. The sacrificial layer 54 of FIG. 7e may be eliminated resulting in a removal of the silicon support layer 55 as shown in FIG. 7f. Another sacrificial layer and a silicon wafer or other support may be placed on the side with layer 59. In FIG. 7g, a mask 64 may be placed on layer 53. With the mask in place, channels 65 may be etched down to the metal 52 of via 51. Mask 64 may be removed in FIG. 7i. Connections may be made to the metal 52 of via 51 on one side and to metal 63 of via 62 on the other side of the flex circuit. The flex circuit may be increased with layers added to one and/or the other side of the circuit.

In the present specification, some of the matter may be of a hypothetical or prophetic nature although stated in another manner or tense.

Although the invention has been described with respect to at least one illustrative example, many variations and modifications will become apparent to those skilled in the art upon reading the present specification. It is therefore the intention that the appended claims be interpreted as broadly as possible in view of the prior art to include all such variations and modifications.

What is claimed is:

1. A method for making a sub-mil flexible circuit comprising:
providing a thin layer of polyimide material;
forming a metal layer on a first surface of the polyimide material;
clamping the polyimide layer in a fixture;
masking the metal layer;
effecting a pattern of the mask onto the metal layer; and
removing the mask.

2. The method of claim 1, further comprising depositing film materials and/or components on the metal layer and/or exposed portions of the polyimide layer.

3. The method of claim 1, further comprising forming a metal layer on a second surface of the polyimide layer.

4. The method of claim 3, further comprising making a via through the polyimide for connecting the metal layer on the first surface of the polyimide layer to the metal layer on the second surface of the polyimide layer.

5. The method of claim 3, wherein:
the polyimide layer has a sub-mil thickness; and
the metal layers have sub-mil thicknesses.

6. The method of claim 2, wherein the film materials and components have near micron or sub-micron dimensions.

7. The method of claim 1, further comprising attaching one or more integrated circuits to one or more layers.

8. The method of claim 3, further comprising applying a second polyimide layer to at least one of the metal layers.

9. The method of claim 8, further comprising:
applying a metal layer on an exposed surface of the second polyimide layer; and
effecting a pattern on the metal layer on the surface of the second polyimide layer.

10. The method of claim 2, further comprising applying polyimide and metal layers for expanding the flexible circuit.

11. The method of claim 2, further comprising dicing the flexible circuit into a plurality of flexible circuits.

12. A flexible circuit comprising:
a dielectric layer having first and second surfaces;
a first metal layer formed on the first surface of the dielectric layer; and
wherein:
the dielectric layer has a sub-mil thickness; and
the first metal layer has a sub-mil thickness.

13. The circuit of claim 12, wherein the first metal layer has a pattern of electrical conductors and components.

14. The circuit of claim 13, further comprising:
a second metal layer formed on a second surface of the dielectric layer; and
at least one conductive via through the dielectric for electrical contact between the first and second metal layers.

15. The circuit of claim 14, wherein:
dielectric layer, and the first and second metal layers are clamped in a fixture during fabrication of the flexible circuit; and
a lift-off resist layer formed on the second dielectric layer; and
a photosensitive resist layer formed on the lift-off resist layer.

16. The circuit of claim 13, further comprising:
a second dielectric layer formed on the first metal layer; and
wherein the second dielectric layer has an opening to at least one bond pad on the first metal layer.

17. The circuit of claim 16, further comprising:
a plurality of dielectric layers; and
a plurality of patterned metal layers having layers situated on and in between the layers of the plurality of dielectric layers; and one or more vias for connecting two or more metal layers to one another.

18. An approach for fabricating a flexible circuit, comprising:
providing a first dielectric layer having a first metal layer formed on a first side of the first dielectric layer;
forming a first dielectric layer;
forming a first metal layer on a first side of the first dielectric layer;
situating a mask having a pattern on the first metal layer;
processing the pattern into the first metal layer;
removing the mask;
forming a second dielectric layer on the first metal layer;
forming a lift-off resist layer on the second dielectric layer;
forming a photosensitive resist layer having a pattern of at least one opening on the lift-off resist layer;
etching at least one opening through the lift-off resist layer and the second dielectric layer forming an opening through the lift-off resist layer and second dielectric layer to the first metal layer; and
depositing a metal towards the at least one opening to form at least one bond pad on the first metal layer.

19. The approach of claim 18, further comprising:
removing the lift-off resist layer;
forming a second metal layer on a second side of the first dielectric layer; and
repeating the steps from situating a mask with a pattern on the first metal layer through removing the lift-off resist layer for the second metal layer in lieu of the first metal layer, and a third dielectric layer in lieu of the second dielectric layer.

20. the approach of claim 19, wherein the first dielectric layer, and the first and second metal layers are a sub-mil thick Kapton™ layer with plated copper on each side.
